(19) United States
(12) Patent Application Publication
(10) Pub. No.: US 2009/0246957 A1
(43) Pub. Date: Oct. 1, 2009

(54) POLISHING LIQUID AND POLISHING METHOD

(75) Inventor: Tetsuya KAMIMURA, Shizuoka-ken (JP)

Correspondence Address: Moss & Burke, PLLC, 401 Holland Lane, Suite 407, Alexandria, VA, 22314, US

(73) Assignee: FUJIFILM CORPORATION, Tokyo (JP)

(21) Appl. No.: 12/406,117

(22) Filed: Mar. 18, 2009

(30) Foreign Application Priority Data
Mar. 27, 2008 (JP) 2008-082982

(51) Int. Cl. H01L 21/306; C09K 13/00

(52) U.S. Cl. 438/693; 252/79.1; 257/E21.23

(57) ABSTRACT

A polishing liquid is provided with which a polishing rate relative to a conductive metal wiring typically represented by a copper wiring on a substrate having a barrier layer containing manganese and/or a manganese alloy and an insulating layer on the surface (particularly, copper oxide formed at the boundary) is decreased and with which less step height between the conductive metal wiring and the insulating layer is formed, and a polishing method using the polishing liquid is also provided. The polishing liquid includes: colloidal silica particles exhibiting a positive ζ potential at the surface thereof, a corrosion inhibiting agent; and an oxidizing agent, in which the polishing liquid is used in a chemical mechanical polishing process for a semiconductor device having, on a surface thereof, a barrier layer containing manganese and/or a manganese alloy, a conductive metal wiring, and an insulating layer.

### CROSS-REFERENCE TO RELATED APPLICATION

This application claims priority under 35 USC 119 from Japanese Patent Application No. 2008-082982, the disclosure of which is incorporated by reference herein.

### BACKGROUND OF THE INVENTION

1. Field of the Invention

The present invention relates to a polishing liquid and a polishing method. In particular, the invention relates to a polishing liquid which is used for polishing a semiconductor substrate having a barrier layer containing manganese and/or a manganese alloy, and a polishing method using the polishing liquid.

2. Description of the Related Art

In recent years, in the development of semi-conductor devices exemplified by semiconductor integrated circuits such as large scale integration circuits (hereinafter, referred to as “LSI”), increased density and integration through refining and lamination of wirings have been demanded in recent years in order to decrease the size and increase the operation speed of semiconductor devices. For this purpose, various techniques such as chemical mechanical polishing (hereinafter sometimes referred to as “CMP”) have been used. CMP is an essential technology for surface planarization of processed layers, such as interlayer insulation films, plug formation, formation of embedded metal wirings, and the like, and CMP performs smoothing of a substrate and eliminates excessive metallic thin films from wiring formation, and eliminates excessive barrier layer on the surface of insulating films.

A general CMP method is performed by attaching a polishing pad on a disk-shaped polishing surface plate (platen), immersing the surface of the polishing pad in a polishing liquid, pressing the surface of a substrate (wafer) (surface to be polished) to the pad and rotating both the platen and the substrate while applying a predetermined pressure (polishing pressure) from the back surface thereof, to thereby planarize the surface of the wafer by mechanical friction generated therebetween.

When a semiconductor device such as an LSI is manufactured, fine wirings are formed in multilayers, in which, when forming a metal wiring of Cu or the like, a film of a barrier metal such as Ta, TaN, Ti or TiN is formed in each layer in advance to prevent diffusion of a wiring material to an inter-layer insulating film, or to improve the adhesion of the wiring material.

In order to form each wiring layer, in general, a CMP process (hereinafter, referred to as “metallic film CMP) is first performed with respect to a metallic film at a single stage or at multiple stages to remove excess wiring material that has been deposited by plating or the like, and thereafter, a CMP process is carried out to remove barrier metal material (barrier metal) that has been exposed on the surface of the metallic film (hereinafter, referred to as “barrier metal CMP”).

A metal polishing liquid employed in CMP generally includes abrasive grains (for example, aluminum oxide or silica) and an oxidizing agent (for example, hydrogen peroxide or persulfuric acid). The basic polishing mechanism is thought to be that the metal surface is oxidized with the oxidizing agent, and then the oxide film formed thereby is removed with the abrasive grains.

The following have been proposed with regard to a polishing liquid containing this type of solid abrasive grains: a CMP polishing agent and a polishing method that aim to achieve a high polishing rate with substantially no occurrence of scratching (for example, Japanese Patent Application Laid-Open (JP-A) No. 2003-17446); a polishing composition and a polishing method for improving washability in CMP (for example, JP-A No. 2003-142435); and a polishing composition that aims to prevent agglomeration of abrasive grains (for example, JP-A No. 2000-84832).

In recent years, to reduce costs and improve performance, it has been attempted to form a film using a manganese compound instead of using Ta as the barrier layer on an insulating layer and apply a heat treatment, thereby forming a self-organized manganese barrier layer including a manganese compound as a main component.

However, such a self-organized manganese barrier layer has met with problems such as that a large slit (step height at the boundary) tends to be generated due to the formation of a large amount of copper oxide at a boundary between conductive metal wiring (for example, copper wiring) and an insulating layer.

### SUMMARY OF THE INVENTION

The present invention is intended to provide a polishing liquid with which a polishing rate relative to a conductive metal wiring typically represented by a copper wiring on a substrate having a barrier layer containing manganese and/or manganese alloy and an insulating layer on the surface (particularly, copper oxide formed at the boundary) is decreased and with which less step height between the conductive metal wiring and the insulating layer is formed, as well as a polishing method using the polishing liquid.

According to an aspect of the invention, there is provided a polishing liquid including:

colloidal silica particles exhibiting a positive ζ potential at the surface thereof;

a corrosion inhibiting agent; and

an oxidizing agent,

wherein the polishing liquid is used for polishing a barrier layer mainly including manganese and/or a manganese alloy and an insulating layer in a chemical mechanical polishing process for a semiconductor device having, on a surface thereof, the barrier layer, a conductive metal wiring, and the insulating layer.

According to another aspect of the invention, there is provided a method of polishing a barrier layer mainly including manganese and/or a manganese alloy and an insulating layer in a chemical mechanical polishing process for a semiconductor device having, on a surface thereof, the barrier layer, a conductive metal wiring, and the insulating layer, the method including:

polishing the barrier layer and the insulating layer using a polishing liquid including a colloidal silica particle exhibiting a positive ζ potential at the surface thereof, a corrosion inhibiting agent, and an oxidizing agent.

### DETAILED DESCRIPTION OF THE INVENTION

According to an exemplary embodiment of the invention, a polishing liquid is provided with which a polishing rate relative to a conductive metal wiring typically represented by a copper wiring on a substrate having a barrier layer containing manganese and/or a manganese alloy and an insulating layer on the surface (particularly, copper oxide formed at the boundary) is decreased and with which less step height between the conductive metal wiring and the insulating layer is formed. According to another exemplary embodiment of the invention, a polishing method using the polishing liquid is provided.

Polishing Liquid

The polishing liquid according to the exemplary embodiment of the invention is used for polishing a barrier layer mainly including manganese and/or a manganese alloy and an insulating layer in a chemical mechanical polishing process for a semiconductor device having, on a surface thereof, the barrier layer, a conductive metal wiring, and an insulating layer. The polishing liquid includes colloidal silica particles exhibiting a positive ζ potential at the surface thereof, a corrosion inhibiting agent, and an oxidizing agent.

It is thought that the polishing liquid of the invention having the composition described above can modify the charge at the surface of polishing particles to a positive charge and can suppress polishing of copper oxide formed at the boundary between the barrier layer containing manganese and/or a manganese alloy at the surface and an insulating layer, by using a cationic compound together with the polishing particles.

The “polishing liquid” of the invention indicates not only the polishing liquid when used in polishing (i.e. the polishing liquid when diluted as required), but also the polishing liquid when in a concentrated form. A concentrated liquid or a concentrated polishing liquid as used herein refers to a polishing liquid in which the concentration of a solute is at a higher level than that of the polishing liquid when used in polishing, and which is used by diluting with water or an aqueous solution upon polishing. The dilution rate is typically 1 to 20 times in volume. The expressions “concentrate” and “concentrated liquid” in the present specification are used to indicate the meanings of the conventionally used expressions “condensate” or “condensed liquid”, i.e., a more concentrated state than the state when employed, rather than the meanings of general terminology that relate to a physical concentration process such as evaporation, and the like.

Colloidal Silica Particle Exhibiting Positive ζ Potential at the Surface

The polishing liquid includes colloidal silica exhibiting a positive ζ potential at the surface thereof as at least a portion of abrasive grains.

The colloidal silica is not particularly limited so long as it exhibits a positive ζ potential at the surface thereof. The colloidal silica is preferably colloidal silica exhibiting a positive ζ potential at the surface thereof in which a cationic compound is adsorbed onto the surface of colloidal silica having a negative charge. That is, it is preferred that the polishing liquid includes colloidal silica having a negative charge, an oxidizing agent, a corrosion inhibiting agent, and a cationic compound so that the cationic compound is adsorbed onto the surface of the colloidal silica to provide colloidal silica exhibiting a positive ζ potential at the surface thereof.

The colloidal silica of which surface is to be modified is preferably colloidal silica which is obtained by hydrolysis of an alkoxysilane and which does not contain impurities such as alkali metals in the inside of the particle thereof. On the other hand, colloidal silica prepared by a method of removing an alkali from an aqueous solution of alkali silicate can also be used. However, the alkali metal remaining in the inside of the particle gradually may leach to give undesired effects on the polishing performance. From such a viewpoint, the colloidal silica that is obtained by hydrolysis of alkoxysilane is more preferred as the raw material of the colloidal silica particles.

The particle diameter of the colloidal silica as the raw material is properly selected depending on the purpose of use of the abrasive grains and it is preferably in a range of from 5 nm to 100 nm.

First, description is to be made to colloidal silica having a cationic compound adsorbed on the surface thereof as one of colloidal silica exhibiting a positive ζ potential at the surface thereof.

Examples of the cationic compound used herein include a compound represented by the following Formula (I) and a compound represented by the following Formula (II) from a viewpoint of not significantly deteriorating the polishing performance to other kinds of films. The compound represented by Formula (I) and the compound represented by Formula (II) are to be described. The compound represented by Formula (I) and the compound represented by Formula (II) may also be referred to as “specific cationic compound(s)”.

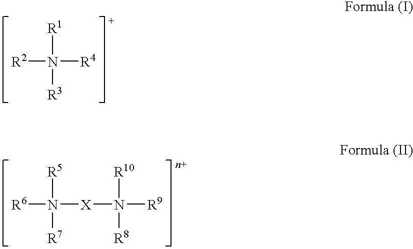

R¹ to R⁴ shown in Formula (I) and R⁵ to R¹⁰ shown in Formula (II) each independently represent an alkyl group having 1 to 20 carbon atoms, an alkenyl group, a cycloalkyl group, an aryl group, or an aralkyl group; two of R¹ to R⁴ may bond to each other; and two of R⁵ to R¹⁰ may bond to each other. The substituents represented by R¹ to R⁴ and R⁵ to R¹⁰ may each be further substituted by another substituent, and examples of the another substituent include an alkyl group and functional groups such a hydroxyl group, an amino group, and a carboxyl group. In Formula (II), X represents a linking group such as an alkylene group having 1 to 30 carbon atoms, an alkenylene group, a cycloalkylene group, or an arylene group or a linking group having a combination of two or more of these groups. The linking group may be further substituted by another substituent, and examples of the another substituent include an alkyl group and functional group such as a hydroxyl group, an amino group, or a carboxyl group. X may further include a nitrogen atom in a quaternary amine form in a structure thereof. In Formula (II), n represents an integer of 2 or larger.

Specific examples of the alkyl group having 1 to 20 carbon atoms include a methyl group, an ethyl group, a propyl group, a butyl group, a pentyl group, a hexyl group, a heptyl group, and an octyl group. Among them, a methyl group, an ethyl group, a propyl group, and a butyl group are preferred. Examples of the alkenyl group include preferably an alkenyl group having 2 to 10 carbon atoms, and specific examples thereof include a vinyl group, a propenyl group, a butenyl group, a pentenyl group, and a hexenyl group.

Specific examples of the cycloalkyl group include a cyclohexyl group and a cyclopentyl group, and a cyclohexyl group is preferred among them.

Specific examples of the aryl group include a phenyl group and a naphthyl group, and a phenyl group is preferred among them.

Specific examples of the aralkyl group include a benzyl group, and a benzyl group is particularly preferred.

Each of the above-mentioned groups may further have a substituent. Examples of the substituent which can be incorporated include a hydroxyl group, an amino group, a carboxyl group, a phosphoric group, an imino group, a thiol group, a sulfo group, and a nitro group.

X in Formula (II) represents a linking group such as an alkylene group having 1 to 30 carbon atoms, an alkenylene group, a cycloalkylene group, or an arylene group or a linking group having a combination of two or more of these groups.

The linking group represented by X may further include, in a chain thereof, —S—, —S(═O)₂—, —O—, or —C(═O)— in addition to the organic linking group.

Specific examples of the alkylene group having 1 to 10 carbon atoms include a methylene group, an ethylene group, a propylene group, a butylene group, a pentylene group, a hexylene group, a heptylene group, and an octylene group. Among these, an ethylene group and a pentylene group are preferable.

Specific examples of the alkenylene group include an ethenylene group and a propenylene group. Among these, a propenylene group is preferred.

Specific examples of the cycloalkylene group include a cyclohexylene group and a cyclopentylene group. Among these, a cyclohexylene group is preferred.

Specific examples of the arylene group include a phenylene group and a naphthylene group. Among these, a phenylene group is preferred.

Each of the above-mentioned groups may further have a substituent, and examples thereof include a hydroxyl group, an amino group, a carboxyl group, a phosphoric group, an imino group, a thiol group, a sulfo group, and a nitro group.

Specific examples of the cationic compound represented by Formula (1) include tetramethylammonium (hereinafter may be referred to as “TMA”), tetrapropylammonium (hereinafter may be referred to as “TPA”), tetrabutylammonium (hereinafter may be referred to as “TBA”), lauryl trimethyl ammonium, lauryl triethyl ammonium, stearyl trimethyl ammonium, palmityl trimethyl ammonium, octyl trimethyl ammonium, dodecyl pyridinium, decyl pyridinium, and octyl pyridinium.

Among them, TMA, TPA and TBA are particularly preferred from the viewpoint of controlling the polishing rate.

Specific examples of the cationic compound represented by Formula (II) include the following Exemplary Compounds C1 to C47. However, the invention is not limited to them.

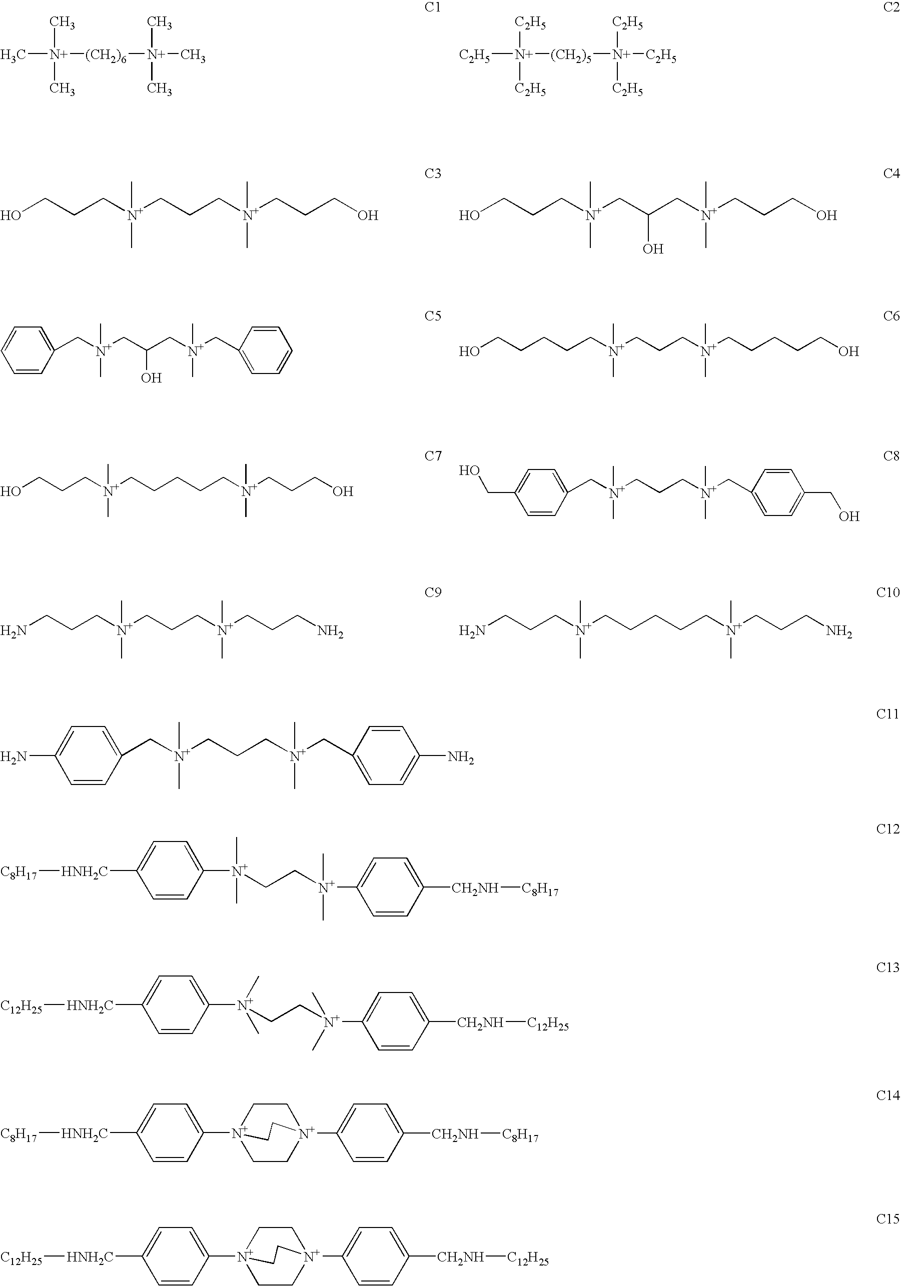

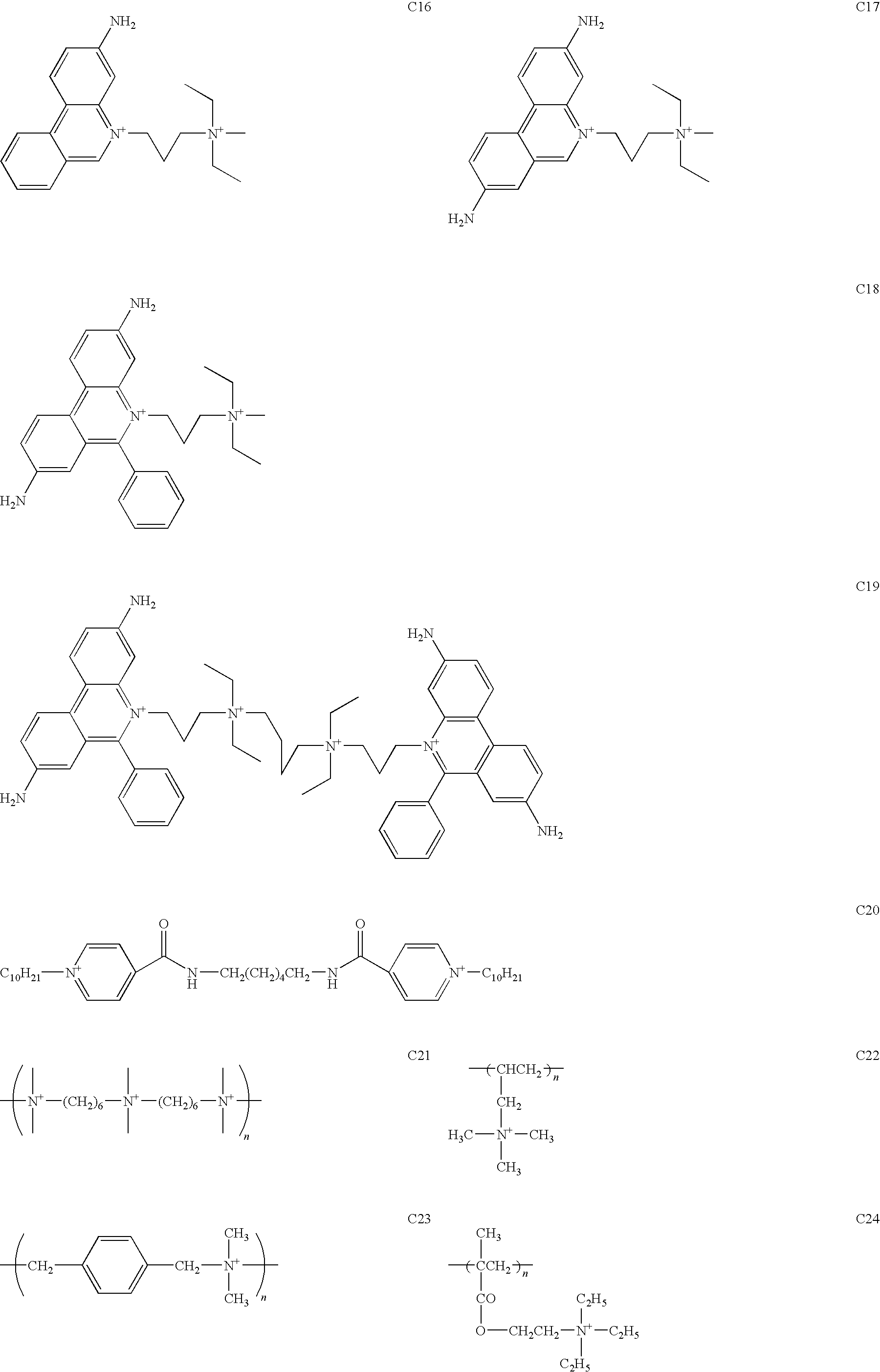

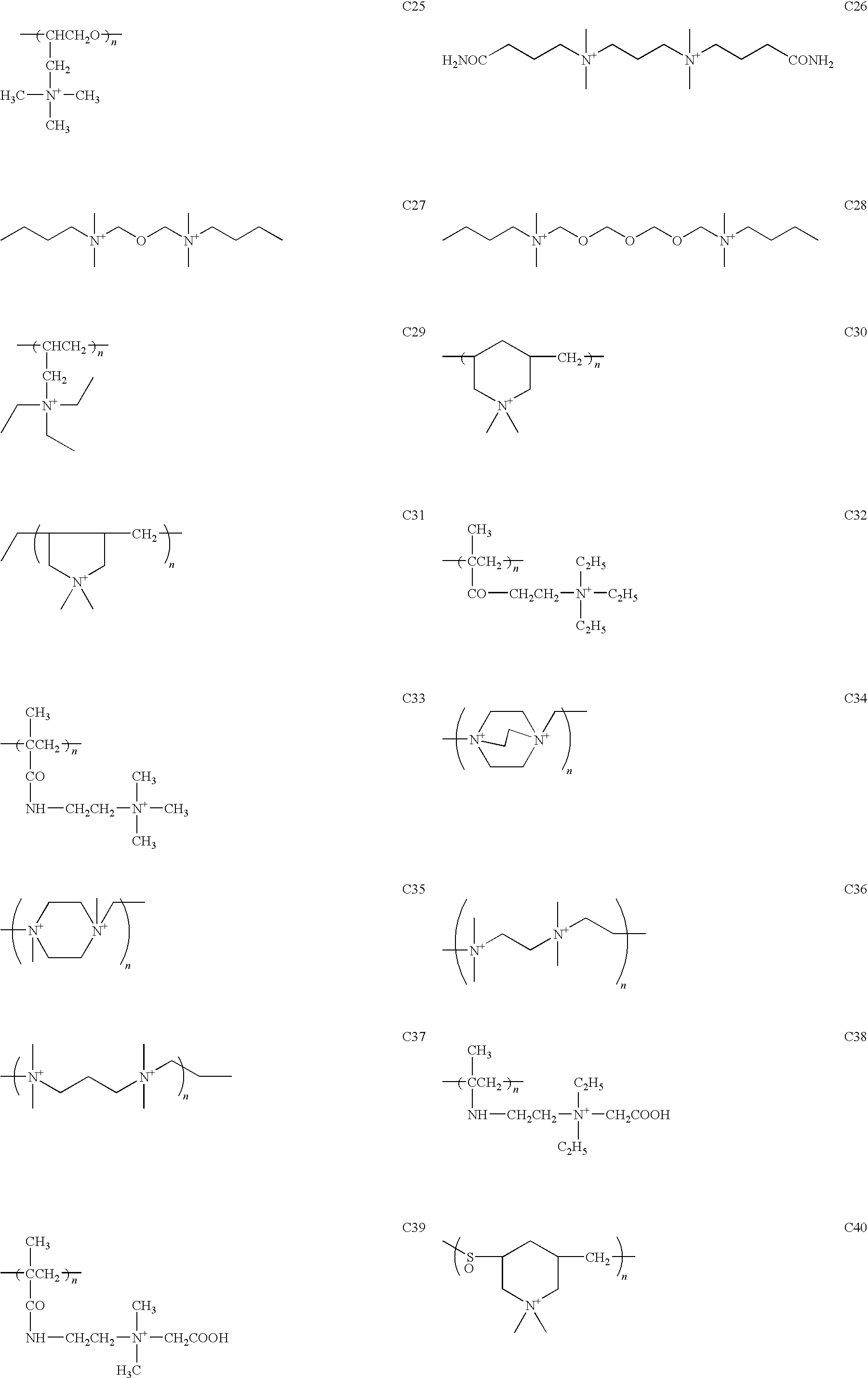

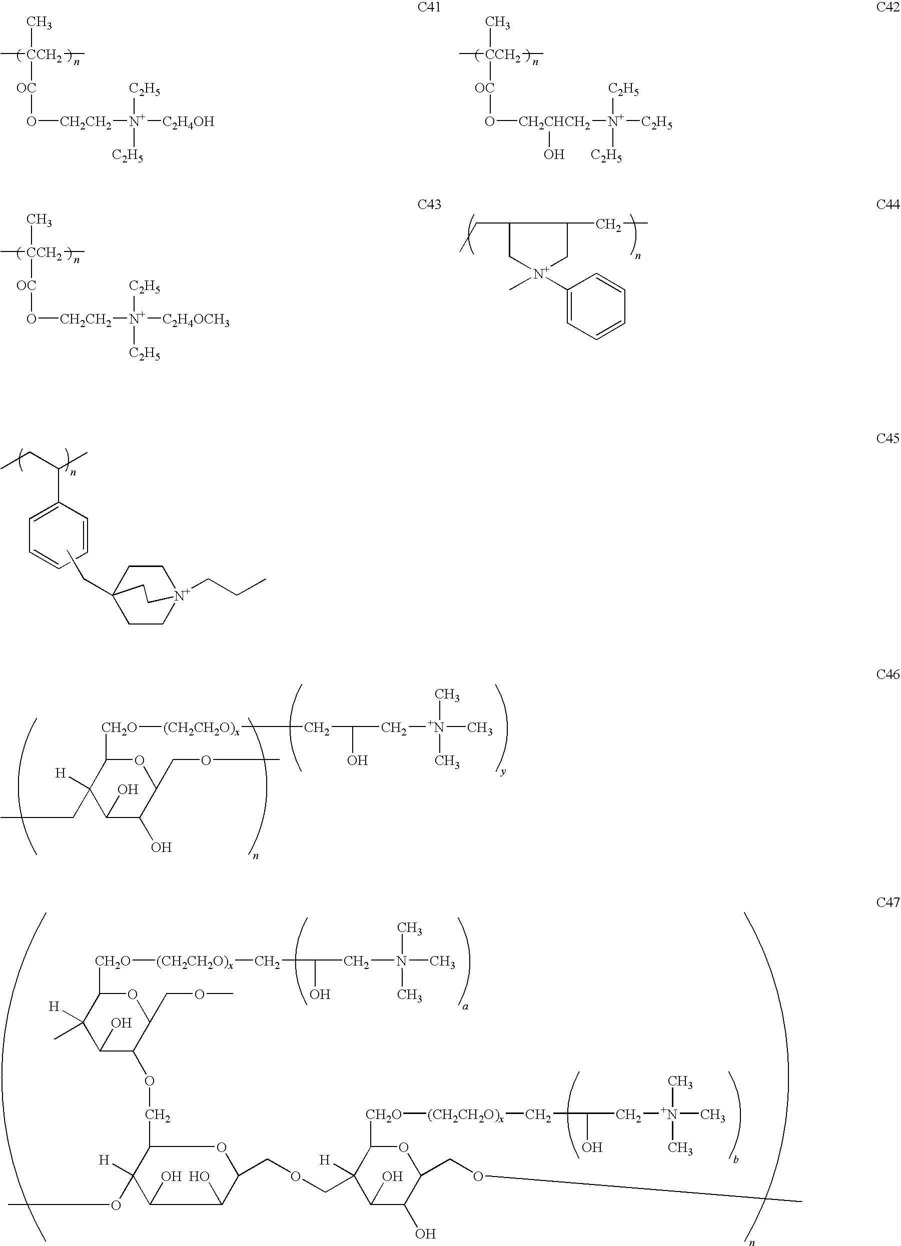

Among the specific Exemplary Compounds C1 to C47, Exemplary Compounds C1 to C3, C12 to C15, C20, and C28 are preferred, and Exemplary Compounds C1 to C3 are more preferred, from a viewpoint of controlling the polishing rate.

In Exemplary Compounds, n is an integer of 2 or larger. In Exemplary Compound C46, x is an integer of from 1 to 50, and y is an integer of from 1 to 50. In Exemplary Compound C47, x is an integer of from 1 to 50, a is an integer of from 1 to 50, and b is an integer of from 1 to 50.

The cationic compound can be synthesized, for example, by a substitution reaction in which ammonia or various amines function as a nucleophile.

Further, the cationic compound can be also purchased as a general commercial reagent.

The concentration of the cationic compound in the polishing liquid of the invention, from a viewpoint of making the surface of the colloidal silica to exhibit a positive ζ potential and controlling the polishing rate, is preferably from 0.00005 mass % to 1 mass %, more preferably from 0.0001 mass % to 0.8 mass %, and particularly preferably from 0.0001 mass % to 0.5 mass %, with respect to the entire mass of the polishing liquid when used in polishing.

Particularly, from a viewpoint of making the surface of the colloidal silica to exhibit a positive ζ potential and controlling the polishing rate, the concentration of the cationic compound represented by Formula (I) is preferably from 0.00005 mass % to 1 mass %, more preferably from 0.0001 mass % to 0.8 mass %, and particularly preferably from 0.0001 mass % to 0.5 mass %, with respect to the entire mass of the polishing liquid when used in polishing.

In the invention, by using the polishing liquid of the invention as a polishing liquid, it is possible to lower the polishing rate with respect to a copper wiring (particularly, copper oxide formed at the boundary) on a substrate including a barrier layer containing manganese and/or a manganese alloy and suppress excess engraving of the copper wiring near the barrier boundary. Formation of a colloidal silica particle exhibiting a positive ζ potential at the surface thereof which can be attained by reacting a cationic compound with a colloidal silica having a negative charge can be confirmed as follows.

When the cationic compound is added to a polishing liquid A including an oxidizing agent and a corrosion inhibiting agent to obtain a polishing liquid B, it can be confirmed whether or not the polishing rate of the polishing liquid B is 80% or less of the polishing rate of the polishing liquid A before addition of the cationic compound. The polishing rate of the polishing liquid B is preferably 50% or less than when using the polishing liquid A.

Thus, it is possible to confirm by the method described above that the colloidal silica particle exhibiting a positive ζ potential at the surface thereof is formed, and that the polishing selectivity to the copper wiring is improved due to the colloidal silica particles exhibiting a positive ζ potential at the surface thereof.

To have the cationic compound adsorb to the surface of the colloidal silica, it may suffice merely to mix the compound and the colloidal silica. Thereby, the cationic compound having the structure as described above is adsorbed on the surface of colloidal silica having a small amount of negative charge to obtain a colloidal silica exhibiting a positive ζ potential at the surface thereof.

In the invention, the ζ potential at the surface of the colloidal silica can be measured, for example, by an electrophoretic method or a supersonic vibration method. As a specific example of the measuring device, DT-1200 (manufactured by Nihon Rufuto Co. Ltd.), etc. can be used.

The amount of the colloidal silica exhibiting a positive ζ potential at the surface thereof in the polishing liquid of the invention is preferably from 0.5 mass % to 10 mass %, more preferably from 0.5 mass % to 8 mass %, and particularly preferably from 1 mass % to 7 mass %, with respect to the entire mass of the polishing liquid (which means hereinafter a polishing liquid when used for polishing, that is, a polishing liquid after dilution when it is diluted with water or an aqueous solution; “polishing liquid when used for polishing” also has the same meaning). In other words, the amount of the colloidal silica is preferably 0.5 mass % or more to polish the barrier layer at a sufficient polishing rate, and preferably 10 mass % or less to obtain a desired storage stability.

The polishing liquid of the invention may further include other abrasive grains than the colloidal silica exhibiting a positive ζ potential at the surface thereof unless the other abrasive grains impair the effect of the invention. In this case, the amount of the colloidal silica exhibiting a positive ζ potential at the surface thereof with respect to the total abrasive grains is preferably, 0 mass % or more, and particularly preferably 80 mass % or more. All of the abrasive grains to be included may be the colloidal silica exhibiting a positive ζ potential at the surface thereof.

Examples of the other abrasive grains that can be used together with the colloidal silica exhibiting a positive ζ potential at the surface thereof in the polishing liquid of the invention include fumed silica, ceria, alumina, and titania. The size of the other abrasive grains to be used together is preferably equal to or larger than the size of the colloidal silica exhibiting a positive ζ potential at the surface thereof, and less than twice the size of the colloidal silica exhibiting a positive ζ potential at the surface thereof.

Corrosion Inhibiting Agent

The polishing liquid may further include a corrosion inhibiting agent that inhibits corrosion of the metallic surface by adsorbing to the surface to be polished and forming a film thereon. The corrosion inhibiting agent as used in the present invention preferably includes a heteroaromatic ring compound containing at least three nitrogen atoms in the molecule thereof and having a condensed ring structure. The “at least three nitrogen atoms” as used herein are preferably atoms constituting the condensed ring. Examples of the heteroaromatic ring compound include tetrazoles, benzotriazoles and derivatives thereof obtained by incorporating a substituent group of various kinds into the benzotriazole.

Examples of the corrosion inhibiting agent usable in the invention include compounds selected from the group consisting of benzotriazole (hereinafter may be referred to as “BTA”), 1,2,3-benzotriazole, 5,6-dimethyl-1,2,3-benzotriazole, 1-(1,2-dicarboxyethyl)benzotriazole, and 1-[N,N-bis(hydroxyethyl)aminomethyl]benzotriazole, 1-(hydroxymethyl)benzotriazole. Of these, the compounds selected from the group consisting of 1,2,3-benzotriazole, 5,6-dimethyl-1,2,3-benzotriazole, 1-(1,2-dicarboxyethyl)benzotriazole, 1-[N,N-bis(hydroxyethyl)aminomethyl]benzotriazole, and 1-(hydroxymethyl)benzotriazole.

Examples of the terazoles include 1H-tetrazole, 5 -phenyl tetrazole, and 5 -methyl tetrazole.

The concentration of the corrosion inhibiting agent is preferably from 0.001 mass % to 1 mass %, and more preferably from 0.01 mass % to 1 mass %, with respect to the entire mass of the polishing liquid when used in polishing. That is, the addition amount of the corrosion inhibiting agent is preferably 0.001 mass % or more from a viewpoint of not extending dishing, and preferably 1 mass % or less from a viewpoint of storage stability.

Oxidizing Agent

The polishing liquid of the invention may further include a compound that oxidizes a metal as an object of polishing (i.e. oxidizing agent).

Examples of the oxidizing agent include hydrogen peroxide, peroxides, nitrates, iodates, periodates, hypochlorites, chlorites, chlorates, perchlorates, persulfates, bichromates, permanganates, ozone water, silver (II) salts, and iron (III) salts. Among them, hydrogen peroxide is used preferably.

Examples of the iron (III) salt include inorganic iron (III) salts such as iron nitrate (III), iron chloride (III), iron sulfate (III), and iron bromide (III), and organic complex salts of iron (III).

The concentration of the oxidizing agent can be controlled depending on the dishing amount at the time of starting CMP of the barrier metal (barrier CMP). When the dishing amount at the time of starting the barrier CMP is large, that is, when the wiring material is not intended to heavily polished in the barrier CMP, it is desirable to use the oxidizing agent in a lower amount. When the dishing amount is sufficiently small and the wiring material is intended to be polished at a high speed, it is desirable to increase the amount of the oxidizing agent. As described above, it is desirable to change the amount of the oxidizing agent depending on the state of dishing at the time of starting the barrier CMP. Specifically, the amount of the oxidizing agent is preferably from 0.01 mol to 1 mol, and particularly preferably from 0.05 mol to 0.6 mol, in 1 L of the polishing liquid when used in polishing.

Other Components

The polishing liquid of the invention may further include various ingredients depending on the purpose, in addition to the ingredients described above. Description is to be made to the ingredients that can be additionally added to the polishing liquid of the invention.

Zwitterionic Compound

The polishing liquid of the invention may further include a zwitterionic compound.

In the polishing liquid of the invention, the ζ potential of the colloidal silica particle can be finely controlled easily and the polishing rate can be controlled easily by controlling the kind and the amount of the zwitterionic compound.

The zwitterionic compound is an electric dipolar compound formed by transfer of a proton in a molecule of an amphoteric electrolyte containing both an acidic group and a basic group. Examples of the zwitterionic compound include betaine (N,N,N-trimethyl ammonia acetate) and glycine. While the zwitterionic compound has no static charge as a whole, it has a dipole moment due to charge separation in the molecule thereof. A protein contains a number of amino groups and carboxyl groups in the molecule thereof, and has both positive and negative charges by ionization of the amino groups and carboxyl groups and becomes a zwitterion in water.

In the invention, the zwitterionic compound is preferably betaine (N,N,N-trimethyl ammonio acetate). The amount of the zwitterionic compound is preferably from 0.0001 mass % to 1 mass %, and more preferably from 0.001 mass % to 0.5 mass %, with respect to the entire mass of the polishing liquid when used in polishing.

Carboxylic Acid Polymer

The polishing liquid of the invention may further include a carboxylic acid polymer with a viewpoint of controlling the polishing rate.

The carboxylic acid polymer is not particularly limited so long as it is a polymer having a carboxyl group. The carboxylic acid polymer has a molecular weight of preferably from 500 to 1,000,000, and more preferably from 1,000 to 500,000. Examples of the carboxylic acid polymer include pectinic acid, polyaspartic acid, polyglutamic acid, polylysine, polymalic acid, polymethacrylic acid, polyamide acid, polymaleic acid, polyitaconic acid, polyfumaric acid, poly(p-styrene carboxylic acid), polyacrylic acid, and polyglyoxylic acid. Among them, polyacrylic acid and polymethacrylic acid are preferred.

The amount of the carboxylic acid polymer is preferably from 0.0001 mass % to 3 mass % with respect to the entire mass of the polishing liquid when used in polishing.

Water-Soluble High-Molecular-Weight Compound

The polishing liquid of the invention may further include a water-soluble high-molecular-weight compound, in addition to the carboxylic polymer with a view point of further smoothening. Specifically, the polishing liquid may further include at least one water-soluble high-molecular-weight compound selected from the group consisting of agar, polyvinyl alcohol, polyvinyl pyrrolidone, polyacrylamide, and a sodium salt of polyacrylic acid. Among them, polyvinyl alcohol is preferred.

The amount of the water-soluble high-molecular-weight compound is preferably from 0.0001 g to 10 g, and more preferably from 0.001 g to 5 g, in 1 L of the polishing liquid when used in polishing from a viewpoint of aging stability. Further, the weight average molecular weight of the water-soluble high-molecular-weight compound is preferably from 200 to 500,000 and more preferably from 1,000 to 300,000, from a viewpoint of aging stability.

Surfactant

The polishing liquid of the invention may further include a surfactant.

In the polishing liquid of the invention, it is possible to improve the polishing rate or control the polishing rate for the insulating layer more preferably by controlling the kind and the amount of the surfactant. Examples of the surfactant include nonionic surfactants and anionic surfactants.

Among them, from a viewpoint of improving the polishing rate for the insulating layer, a compound represented by the following Formula (III) is preferred.

R—SO₃⁻ Formula (III)

In Formula (III), R represents a hydrocarbon group and preferably represents a hydrocarbon group having 6 to 20 carbon atoms. Specifically, R may represent an alkyl group having 6 to 20 carbon atoms or an aryl group having 6 to 20 carbon atoms (for example, a phenyl group or a naphthyl group). The alkyl group or the aryl group may further have a substituent such as an alkyl group.

Specific examples of the compound represented by Formula (III) include those compounds such as decylbenzene sulfonic acid, dodecylbenzene sulfonic acid (DBSA), tetradecylbenzene sulfonic acid, hexadecylbenzene sulfonic acid, dodecylnaphthalene sulfonic acid, and tetradecylnaphthalene sulfonic acid.

As the surfactant to be used in the invention, other surfactants than the compounds represented by Formula (III) may also be used. Examples of the surfactants other than the compounds represented by Formula (III) include anionic surfactants such as carboxylic acid salts, sulfuric acid ester salts, and phosphoric acid ester salts. Specific examples of the carboxylic acid salts usable herein include soaps, N-acylamino acid salts, polyoxyethylene alkyl ether carboxylic acid salts, polyoxypropylene alkyl ether carboxylic acid salts, and acylated peptides.

Specific examples of the sulfuric acid ester salts include sulfated oils, alkyl sulfuric acid salts, alkyl ether sulfuric acid salts, polyoxyethylene alkyl allyl ether sulfuric acid salts, polyoxypropylene alkyl allyl ether sulfuric acid salts, and alkyl amide sulfuric acid salts.

Specific examples of the phosphoric acid ester salts include alkyl phosphoric acid salts, polyoxyethylene alkyl allyl ether phosphoric acid salt, and polyoxypropylene alkyl allyl ether phosphoric acid salt.

The total amount of the surfactants is preferably from 0.001 to 10 g, more preferably from 0.01 to 5 g, and particularly preferably from 0.01 to 1 g, in 1 L of the polishing liquid when used in polishing. That is, the total amount of the surfactants is preferably 0.001 g or more in 1 L of the polishing liquid when used in polishing from the viewpoint of obtaining a sufficient effect, and preferably 10 g or less in 1 L of the polishing liquid when used in polishing from the viewpoint of preventing lowering of the CMP rate.

Complexing Agent

The polishing liquid of the invention may further include or may not include a complexing agent.

The complexing agent may be at least one organic acid selected from compounds having at least one carboxyl group in the molecule thereof, and is not particularly limited so long as it is a compound having at least one carboxyl group in the molecule thereof. The complexing agent is preferably a compound represented by the following Formula (V) from a viewpoint of polishing rate.

The number of the carboxyl groups present in the molecule is preferably from 1 to 4, and more preferably from 1 to 2 from a viewpoint of a low cost.

R⁷—O—R⁸—COOH Formula (V)

In Formula (V), R⁷ and R⁸ each independently represent a hydrocarbon group and preferably represent a hydrocarbon group having 1 to 10 carbon atoms.

R⁷ specifically represent a monovalent hydrocarbon group such as an alkyl group having 1 to 10 carbon atoms (for example, a methyl group and a cycloalkyl group), an aryl group (for example, a phenyl group), an alkoxy group, or an aryloxy group.

R⁸ specifically represent a bivalent hydrocarbon group such as an alkylene group having 1 to 10 carbon atoms (for example, a methylene group and a cycloalkylene group), an arylene group (for example, a phenylene group) or an alkyleneoxy group.

The hydrocarbon groups represented by R⁷ and R⁸ may each further have a substituent. Examples of the additional substituent that can be introduced include an alkyl group having 1 to 3 carbon atoms, an aryl group, an alkoxy group, and a carboxyl group. When the hydrocarbon group represented by R⁷ or R⁸ further includes the carboxyl group as the additional substituent, the compound has plural carboxyl groups.

Further, R⁷ and R⁸ may bond to each other to form a ring structure.

Examples of the complexing agent in the invention include formic acid, acetic acid, propionic acid, butyric acid, valeric acid, 2-methyl butyric acid, n-hexanoic acid, 3,3-dimethyl butyric acid, 2-ethyl butyric acid, 4-methyl pentanoic acid, n-heptanoic acid, 2-methyl hexanoic acid, n-octanoic acid, 2-ethyl hexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, and salts thereof such as ammonium salts thereof or alkali metal salts thereof, sulfuric acid, nitric acid, ammonia, ammonium salts and mixtures thereof.

Among them, formic acid, malonic acid, malic acid, tartaric acid, and citric acid are suitable to a laminate film containing at least one layer of metal selected from copper, a copper alloy, and an oxide of copper or an oxide of a copper alloy.

Additional examples of the complexing agent in the invention include amino acids and the like. As the amino acid or the like, those having water solubility are preferred, and those selected from the following group are more suitable.

That is, the complexing agent is preferably at least one amino acid selected from the group consisting of glycin, L-alanine, β-alanine, L-2-amino butyric acid, L-norvaline, L-valine, L-leucine, L-norleucine, L-isoleucine, L-alloisoleucine, L-phenylalanine, L-proline, sarcosine, L-omitin, L-lysine, taurine, L-serine, L-threonine, L-allothreonine, L-homoserine, L-tyrosine, 3,5 -diiodo-L-tyrosine, β-(3,4-dihydroxyphenyl)-L-alanine, L-thyroxin, 4-hydroxy-L-proline, L-cysteine, L-methionine, L-ethionine, L-lanthionine, L-cystathionine, L-cystine, L-cysteic acid, L-aspartic acid, L-glutamic acid, S-(carboxymethyl)-L-cysteine, 4-amino butyric acid, L-asparagine, L-glutamine, azaserine, L-arginine, L-canavanine, L-citrulline, δ-hydroxy-L-lysine, creatine, L-kynurenine, L-hystidine, 1-methyl-L-hystidine, 3-methyl-L-hystidine, ergothioneine, L-triptophan, actinomycin C1, apamin, angiotensin I, angiotensin II, and antipain.

Among them, malic acid, tartaric acid, citric acid, glycine, and glycolic acid are particularly preferred in that the etching rate can be suppressed effectively while maintaining a practical CMP rate.

In the polishing liquid of the invention, the amount of the complexing agent (preferably a compound represented by Formula (V)) is preferably from 0 mass % to 5 mass %, and more preferably from 0 mass % to 2 mass %, with respect to the mass of the polishing liquid when used in polishing. It is most preferred that the complexing agent is not contained (amount: 0 mass %) in the polishing liquid.

pH Regulator

The polishing liquid of the invention preferably has a pH of from 1.5 to 5.0. By adjusting the pH of the polishing liquid in a range from 1.5 to 5.0, the polishing rate for the interlayer insulating film can be more accurately adjusted.

Then, for adjusting the pH to the preferred range, at least one of an alkali, an acid and a buffer may be used as required.

Examples of the alkali, acid and buffer include non-metal alkali agents such as organic hydroxyl ammonium (for example, ammonia, ammonium hydroxide, and tetramethyl ammonium hydroxide), alkanol amines (such as diethanol amine, triethanolamine, and triisopropanolamine), alkali metal hydroxides (such as sodium hydroxide, potassium hydroxide, and lithium hydroxide), inorganic acids (such as nitric acid, sulfuric acid, and phosphoric acid), carbonic acid salts such as sodium carbonate, phosphoric acid salts such as trisodium phosphate, boric acid salts, tetraboric acid salts, and hydroxybenzoic acid salts. Particularly preferred alkali agents are ammonium hydroxide, potassium hydroxide, lithium hydroxide, and tetramethyl ammonium hydroxide.

The amount of at least one of the alkali, acid and buffer may be in such an amount that the pH is maintained in the preferred range. The amount is preferably from 0.0001 mol to 1.0 mol, and more preferably from 0.003 mol to 0.5 mol, in 1 L of the polishing liquid when used for polishing.

Chelating Agent

The polishing liquid preferably further includes a chelating agent (that is, a hard water softening agent) for decreasing undesired effects of polyvalent metal ions or the like to be intruded.

Examples of the chelating agent include general-purpose hard water softening agents and compounds analogous therewith, which are used as precipitation inhibiting agents for calcium or magnesium. Specific examples thereof include nitrilo triacetic acid, diethylene triamine pentaacetic acid, ethylene diamine tetraacetic acid, N,N,N-trimethylene phosphonic acid, ethylene diamine-N,N,N′,N′-tetramethylene sulfonic acid, transcyclohexane diamine tetraacetic acid, 1,2-diaminopropane tetraacetic acid, glycol ether diamine tetraacetic acid, ethylene diamine orthohydroxyphenyl acetic acid, ethylene diamine disuccinic acid (SS form), N-(2-carbolate ethyl)-L-aspartic acid, β-alanine diacetic acid, 2-phosphonobutane-1,2,4-tricarboxylic acid, 1-hydroxyethylidene-1,1-diphosphonic acid, N,N′-bis(2-hydroxybenzyl)ethylene diamine-N,N′-diacetic acid, and 1,2-dihydroxybenzene-4,6-disulfonic acid.

Two or more chelating agents may be used in combination, as required.

It may suffice that the chelating agent is added in such an amount as sufficient to block chelate metal ions, such as polyvalent metal ions, to be intruded. The amount of the chelating agent may be, for example, from 0.0003 mol to 0.07 mol in 1 L of the polishing liquid when used in polishing.

Then, an object of polishing in a case of performing polishing by using the polishing liquid of the invention is to be described. When the polishing liquid of the invention is used, the object of polishing is not particularly limited. The polishing liquid can be used suitably in the polishing step of planarizing the surface of a semiconductor substrate (wafer) in which an inter-layer insulating film, a barrier layer, and a conductive film of copper or a copper alloy are disposed on a silicon substrate in the manufacturing process of a semiconductor device.

Barrier Metal Material

The barrier layer of the semiconductor substrate as the object of polishing may be composed of a material including manganese and/or a manganese alloy. The barrier layer may further include a usual metal material of low resistance, for example, TiN, TiW, Ta, TaN, W, or WN. The polishing liquid of the invention can sufficiently exert the effect of the invention with respect to the barrier layer in which the proportion (amount) of manganese and/or a manganese alloy in the barrier layer is 10 mass % or more, and more preferably 20 mass % or more, with respect to the entire mass of the barrier layer.

The manganese and/or manganese alloy is preferably a material in which a manganese compound forms a barrier layer near the boundary between a conductive metal wiring and an insulating layer by self organization due to excitation energy.

More specifically, when an excitation energy including that of a heating treatment is applied to the manganese compound, the manganese compound undergoes self organization to form a barrier layer.

Examples of the manganese alloy that can be contained in the barrier layer include alloys of manganese (Mn) in combination with at least one of Cu, Al, Ag, and Au, which are used as the wiring metal, and/or at least one of Mn, Ta, Ti, and Ru, which are used as the barrier material, and Cu—Mn is particularly preferred.

Insulating Layer

The insulating layer (inter-layer insulating film) may be a generally-used inter-layer insulating film such as tetraethoxysilane (TEOS), and it is particularly preferably a low-dielectric-constant insulating layer having a dielectric constant (k value) of 2.3 or less and having silicon as a basic skeleton.

Further, the insulating layer may be formed as an inter-layer insulating film further including a material having a low dielectric constant (for example, organic polymer, SiOC, SiOF, materials which are usually referred to simply as Low-k film).

Specific examples of the material used for forming the insulating layer of low dielectric constant include HSG-R7 (manufactured by Hitachi Chemical Co., Ltd.), BLACKDIAMOND (manufactured by Applied Materials, Inc.), SilK (manufactured by Dow Chemical Co.), Aurora (manufactured by manufactured by Nihon ASM Co. Ltd.), and Coral (manufactured by Novellus Systems, Inc.). Such a Low-k film is usually placed below a TEOS insulating film, and a barrier layer and a metal wiring are formed on the TEOS insulating film.

The polishing liquid of the invention can lower the polishing rate of the inter-layer insulating film (insulating layer) by using the colloidal silica particle exhibiting the positive ζ potential at the surface.

Raw Material for Wiring Metal

A substrate to be polished which is an object of polishing may have wirings which are formed from copper metal and/or a copper alloy and may be applied to, for example, semiconductor devices such as LSI. As the raw material for the wiring, copper alloys are particularly preferred. Further, among the copper alloys, copper alloys containing silver are preferred.

The amount of silver included in the copper alloy is preferably 40 mass % or less, more preferably 10 mass % or less, and particularly preferably 1 mass % or less, and a most excellent effect may be obtained when a copper alloy includes silver in an amount of from 0.00001 to 0.1 mass %.

Diameter of Wirings

In the invention, if the substrate, which is an object of polishing, is applied to a dynamic random access memory (DRAM) device, the substrate preferably has wirings having a half pitch of 0.15 μm or less, more preferably 0.10 μm or less, and further preferably 0.08 μm or less.

If the substrate is applied to a micro processing unit (MPU) device, the substrate preferably has wirings having a half pitch of 0.12 μm or less, more preferably 0.09 μm or less, and further preferably 0.07 μm or less.

The polishing liquid exhibits a particularly excellent effect when used for a substrate having wiring configurations such as the above.

Polishing Method

The polishing liquid of the invention may be (a) a concentrated solution which will be diluted with water or an aqueous solution upon use, (b) a set of plural aqueous solutions including respective ingredients as described below, which will be mixed and optionally diluted with water to provide a solution to be used, or (c) a polishing liquid which has been prepared as a solution to be used without requiring further modification.

For the polishing method using the polishing liquid of the invention, the polishing liquid is applicable in any form. Basically, the polishing liquid is supplied to a polishing pad on a polishing platen, and polishing is performed while bringing the surface of a substrate to be polished into contact with the polishing pad and causing relative motion between the surface to be polished and the polishing pad.

As a device used for polishing, a general polishing device including a holder that holds a substrate having a surface to be polished (for example, a wafer on which a conductive material film is formed) and a polishing platen bonded with a polishing pad (attached with e.g. a motor having a variable number of rotations) can be used. The polishing pad is not particularly limited, and general non-woven fabrics, foamed polyurethanes, porous fluoro resins, or the like can be used. Further, while the polishing conditions are not particularly limited, the rotation speed of the polishing platen is preferably at a low rotation of 200 rpm or less so that the substrate is not thrown off. The urging pressure of the substrate having the surface to be polished (film to be polished) with respect to the polishing pad is preferably in a range of from 0.68 to 34.5 kPa, and it is more preferably in a range of from 3.40 to 20.7 kPa in order to achieve a desired uniformity of polishing speed in the plane of the substrate, and a desired planarity of the pattern.

During polishing, the polishing liquid of the invention is supplied continuously by a pump or the like to the polishing pad.

The substrate to be polished is thoroughly washed in running water after completion of the polishing. Then, by using a spin drier or the like, water droplets deposited on the substrate to be polished are shaken off and the substrate is dried.

In the invention, when the concentrated solution is diluted as in the case (a), an aqueous solution shown below can be used. For example, an aqueous solution containing at least one of an oxidizing agent, an organic acid, an additive, or a surfactant is prepared previously such that the total of the ingredients contained in the aqueous solution and the ingredients contained in the diluted concentrated solution form the ingredients of the polishing liquid (solution to be used) used upon polishing.

As described above, when using the concentrated solution diluted with the aqueous solution, since less soluble ingredients can be formulated in the aqueous solution before use, a further concentrated solution can be prepared.

As an example of a method of diluting a concentrated solution of the polishing liquid of the invention by adding water or an aqueous solution thereto, a pipe that supplies the concentrated polishing liquid, and a pipe that supplies water or an aqueous solution may converge to mix the polishing liquid and the water or aqueous solution, and the resulting diluted polishing liquid as a liquid to be used is then supplied to the polishing pad. Mixing of the concentrated solution and water or aqueous solution can be carried out by, for example, a method of colliding and mixing liquids together by passing them through a narrow channel in a pressurized state, a method of mixing by repeatedly separating and joining liquids through the use of stopping elements such as glass tubes or the like provided in a pipe, or a method of disposing a power-rotated vane in the pipe.

The speed of supplying the polishing liquid is preferably in a range of from 10 to 1,000 ml/min, and more preferably in a range of from 170 to 800 ml/min for satisfying the uniformity of the polishing rate in the plane of the substrate and the planarity of the pattern.

Moreover, as another example of the method of polishing while continuing to dilute the concentrated solution with water or an aqueous solution, there is a method in which the pipe for supplying the polishing liquid and the pipe for supplying water or the aqueous solution are separately provided, and predetermined amounts of the liquid and the water or aqueous solution is supplied onto the polishing pad from respective pipes, and polishing is carried out while mixing the liquid and the water or aqueous solution by means of the relative motion between the polishing pad and the surface to be polished. Furthermore, a polishing method may also be employed in which predetermined amounts of the concentrated liquid and the water or aqueous solution are mixed in a single container, and then the mixture is supplied onto the polishing pad.

Moreover, a polishing method may also be used in which the components included in the polishing liquid are divided into at least two constituent components, and the constituent components are diluted, when employed, by adding water or an aqueous solution and supplied onto the polishing pad placed on the surface of the polishing platen, and then brought into contact with the surface to be polished, thereby performing polishing by moving the surface to be polished and the polishing pad relatively.

For example, the components may be divided in such a manner that an oxidizing agent is provided in a constituent component (A), while an organic acid, an additive, a surfactant, and water are provided in a constituent component (B), and at the time of usage, the constituent components (A) and (B) are diluted with water or an aqueous solution.

Alternatively, the additives having low solubility may be separated to be included in either of the two constituent components (A) and (B), for example, in such a manner that the oxidizing agent, additive, and surfactant are provided in the constituent component (A), while the organic acid, additive, surfactant, and water are provided in the constituent component (B), and at the time of usage, the constituent components (A) and (B) are diluted with water or an aqueous solution.

In the case of the exemplary embodiments described above, three pipes that supply the constituent component (A), the constituent component (B), and water or an aqueous solution respectively are necessary. In this case, dilution and mixing may be carried out by a method in which the three pipes are joined into a single pipe for supplying to the polishing pad, and the constituent components and the water or aqueous solution are mixed in the joined pipe. Alternatively, two of the three pipes may be joined first, and the remaining pipe may subsequently be joined further in a downstream direction of the flow of liquid. Specifically, a constituent component including an additive having low solubility and another constituent component may be mixed first, so that the mixing path is lengthened to ensure sufficient time for dissolution, and then subsequently the pipe for supplying water or an aqueous solution may be joined thereto.

Other examples of the mixing method include a method in which the three pipes are directly introduced to the polishing pad and mixing is carried out via a relative motion between the polishing pad and the surface to be polished, and a method in which the three constituent components are mixed in one vessel, and the resultant diluted polishing liquid is then supplied from the vessel to the polishing pad.

In the above-mentioned polishing methods, the temperature of the constituent components may be regulated such that the constituent component including an oxidizing agent has a temperature of 40° C. or less, while other constituent components are heated to a temperature ranging from room temperature to 100° C., and upon mixing these constituent components, or adding water or an aqueous solution for dilution thereto, the resultant solution has a temperature of 40° C. or less. This method is effective for increasing the solubility of a raw material having a low solubility in the polishing liquid, by utilizing a phenomenon whereby solubility is increased by increasing temperature.

The raw materials which are dissolved by heating the other constituent components in a range of from room temperature to 100° C. may precipitate in the solution if the temperature decreases. Therefore, when using the other constituent component when at a low temperature, it is necessary to dissolve the precipitated raw material by heating it in advance. For this purpose, a means to heat the other constituent component to dissolve the raw materials therein and to supply the other constituent component may be used, or a means for stirring a liquid containing precipitates, and sending the liquid through a pipe while heating the pipe to dissolve the precipitates may be used. Since the oxidizing agent may be decomposed by the other heated constituent component when the temperature of the constituent component including the oxidizing agent increases to 40° C. or higher, it is preferable that the temperature is set to 40° C. or lower when the other heated constituent component and the constituent component including the oxidizing agent are mixed.

As described above, according to an exemplary embodiment of the invention, components of the polishing liquid may be divided into two or more portions and supplied to the surface to be polished. In this case, it is preferable that the components are supplied after being divided into a component including the oxidizing agent and a component including the organic acid. Further, the polishing liquid may be prepared as a concentrated solution and supplied separately from diluting water to the surface to be polished.

In the invention, when the method of dividing the components of the polishing liquid into two or more portions and then supplying them to the surface to be polished is employed, the terms “amount of supply” and “supply amount” refer to the total amount of the liquids supplied from respective pipes.

Pad

The polishing pad for polishing applicable to the polishing method of the invention may be a pad formed from a non-foamed body or a pad formed from a foamed body. The pad formed from a non-foamed body may be a rigid synthetic resin bulk material such as a plastic plate. The pad formed from a foamed body may be classified into three: closed cell foam (dry foam system); open cell foam (wet foam system); and a dual layer composite including the closed cell foam and the open cell foam (laminate system). Among them, the dual layer composite body (laminate system) is preferred. Foaming may be uniform or not uniform.

Further, the pad may include abrasive grains used generally for polishing (for example, ceria, silica, alumina, a resin, etc.). Further, the pad may be made of a soft material or a hard material. In a pad of the laminate system, respective layers preferably have different hardnesses. Examples of the material of the pad include non-woven fabric, artificial leather, polyamide, polyurethane, polyester, and polycarbonate. Further, the surface of the pad, which is in contact with the surface to be polished, may be subjected to fabrication of forming at least one of lattice groves, apertures, concentrical grooves, spiral grooves, and the like.

Wafer

The wafer as a substrate which is the object of CMP using the polishing liquid of the invention preferably has a diameter of 200 mm or more, and particularly preferably 300 mm or more. The effect of the invention may be obtained remarkably when the diameter is 300 mm or more.

Polishing Device

The device employing the polishing liquid of the invention in a polishing process is not particularly limited in any manner, and examples thereof include a Mirra Mesa CMP, a Reflexion CMP (both trade names, manufactured by Applied Materials, Inc.), a FREX 200 and a FREX 300 (both trade names, manufactured by Ebara Corporation), an NPS 3301 and an NPS 2301 (both trade names, manufactured by Nikon Corporation), an A-FP-310A and an A-FP-210A (both trade names, manufactured by Tokyo Seimitsu, Co., Ltd.), a 2300 TERES (trade name, manufactured by Lam Research, Co., Ltd.), and a Momentum (trade name, manufactured by SpeedFam-IPEC, Inc.).

Hereinafter, exemplary embodiments of the present invention are described.

(1) A polishing liquid, including:

colloidal silica particles exhibiting a positive ζ potential at the surface thereof,

a corrosion inhibiting agent; and

an oxidizing agent,

wherein the polishing liquid is used for polishing a barrier layer mainly including manganese and/or a manganese alloy and an insulating layer in a chemical mechanical polishing process for a semiconductor device having, on a surface thereof, the barrier layer, a conductive metal wiring, and the insulating layer.

(2) The polishing liquid according to (1), wherein the colloidal silica exhibiting a positive ζ potential at the surface thereof is a colloidal silica in which a cationic compound represented by the following Formula (I) or the following Formula (II) is adsorbed onto the surface of a colloidal silica having a negative charge:

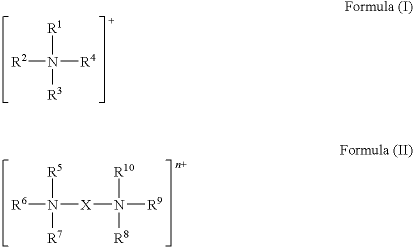

wherein, R¹ to R⁴ in Formula (I) and R⁵ to R¹⁰ in Formula (II) each independently represent an alkyl group having 1 to 20 carbon atoms, an alkenyl group, a cycloalkyl group, an aryl group, or an aralkyl group; two of R¹ to R⁴ may bond to each other; two of R⁵ to R¹⁰ may bond to each other; the substituents represented by R¹ to R⁴ and R⁵ to R¹⁰ each may be further substituted by another substituent; X in Formula (II) represents an alkylene group having 1 to 30 carbon atoms, an alkenylene group, a cycloalkylene group, an arylene group or a linking group having a combination of two or more of these groups; the linking group may further be substituted by another substituent; X may further include a nitrogen atom in a quaternary amine form in a structure thereof, and n in Formula (II) represents an integer of 2 or larger.

(3) The polishing liquid according to (2), wherein the concentration of the cationic compound represented by Formula (I) or Formula (II) is from 0.00005 mass % to 1 mass % with respect to the entire mass of the polishing liquid when used in polishing.

(4) The polishing liquid according to (1), wherein the barrier layer including the manganese and/or a manganese alloy is formed near the boundary between the conductive metal wiring and the insulating layer by self organization of a manganese compound due to excitation energy.

(5 ) The polishing liquid according to (1), wherein the insulating layer includes a low-dielectric-constant insulating layer having silicon as a basic skeleton and having a dielectric constant (k value) of 2.3 or less.

(6) The polishing liquid according to (1), wherein the concentration of the colloidal silica exhibiting a positive ζ potential at the surface thereof is from 0.5 mass % to 10 mass % with respect to the entire mass of the polishing liquid when used in polishing.

(7) The polishing liquid according to (1), wherein the primary average particle diameter of the colloidal silica exhibiting a positive ζ potential at the surface thereof is from 5 nm to 100 nm.

(8) The polishing liquid according to (1), wherein the concentration of the corrosion inhibiting agent is from 0.001 mass % to 1 mass % with respect to the entire mass of the polishing liquid when used in polishing.

(9) The polishing liquid according to (1), wherein the polishing liquid is free from a complexing agent.

(10 ) The polishing liquid according to (1), wherein the polishing liquid has a pH of from 1.5 to 5.0.

(11) The polishing liquid according to (1), further including a zwitterionic compound.

(12) The polishing liquid according to (1), further including a carboxylic acid polymer.

(13) A method of polishing a barrier layer mainly including manganese and/or a manganese alloy and an insulating layer in a chemical mechanical polishing process for a semiconductor device having, on a surface thereof, the barrier layer, a conductive metal wiring, and the insulating layer, the method including:

polishing the barrier layer and the insulating layer using a polishing liquid including a colloidal silica particle exhibiting a positive ζ potential at the surface thereof, a corrosion inhibiting agent, and an oxidizing agent.

(14) The polishing method according to (13), wherein the colloidal silica exhibiting a positive ζ potential at the surface thereof is a colloidal silica in which a cationic compound represented by the following Formula (I) or the following Formula (II) is adsorbed onto the surface of a colloidal silica having a negative charge:

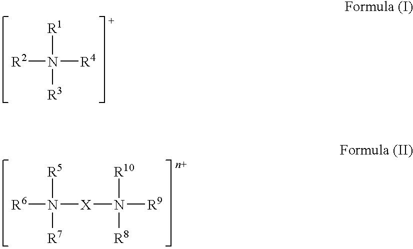

wherein R¹ to R⁴ in Formula (I) and R⁵ to R¹⁰ in Formula (II) each independently represent an alkyl group having 1 to 20 carbon atoms, an alkenyl group, a cycloalkyl group, an aryl group, or an aralkyl group; two of R¹ to R⁴ may bond to each other; two of R⁵ to R¹⁰ may bond to each other; the substituents represented by R¹ to R⁴ and R⁵ to R¹⁰ may each be further substituted by another substituent; X in Formula (II) represents an alkylene group having 1 to 30 carbon atoms, an alkenylene group, a cycloalkylene group, an arylene group or a linking group having such groups in combination; the linking group may further be substituted by another substituent; X may further include a nitrogen atom in a quaternary amine form in a structure thereof, and n in Formula (II) represents an integer of 2 or larger.

(15 ) The polishing method according to (14), wherein the concentration of the cationic compound represented by Formula (I) or Formula (II) is from 0.00005 mass % to 1 mass % with respect to the entire mass of the polishing liquid when used in polishing.

(16) The polishing method according to (13), wherein the barrier layer including manganese and/or a manganese alloy is formed near the boundary between the conductive metal wiring and the insulating layer by self organization of the manganese compound due to excitation energy.

(17) The polishing method according to (13), wherein the insulating layer includes a low-dielectric-constant insulating layer having silicon as a basic skeleton and having a dielectric constant (k value) of 2.3 or less.

All publications, patent applications, and technical standards mentioned in this specification are herein incorporated by reference to the same extent as if each individual publication, patent application, or technical standard was specifically and individually indicated to be incorporated by reference.

### EXAMPLES

The present invention is to be described more specifically by way of examples, but the invention is not restricted to the following examples so long as they are within the gist of the invention.

### Example 1

### Preparation of Polishing Liquid

A polishing liquid having a composition and a pH shown below (polishing liquid of Example 1) was prepared.

### Composition 1

| | | |
|---|---|---|
| Cationic compound: tetrabutylammonium nitrate (TBA) | 1.0 | g/L |
| Corrosion inhibiting agent: benzotriazole (BTA) | 1.0 | g/L |
| Colloidal silica particle: A1 | 100 | g/L |
| Oxidizing agent: hydrogen peroxide | 20 | ml |
| Make-up with pure water to an entire amount | 1,000 | mL |

| | |
|---|---|
| pH (adjusted with aqueous ammonia and nitric acid) | 2.5 |

The shape and the particle diameter of the colloidal silica particle A1 are shown in the following Table 1. PL3, PL3L, PL3H, PL2, and PL2L shown in Table 1 are products available from Fuso Chemical Co., Ltd.

TABLE 1

| | Abrading particles | Particle diameter |
|---|---|---|
| A1 | Colloidal silica | PL3 [35 nm, cocoon-shaped] |
| A2 | Colloidal silica | PL3L [35 nm, spherical] |
| A3 | Colloidal silica | PL3H [35 nm, aggregate] |
| A4 | Colloidal silica | PL2 [25 nm, cocoon-shaped] |
| A5 | Colloidal silica | PL2L [20 nm, spherical] |

Evaluation of polishing using the polishing liquid of Example 1 was conducted.

Evaluation Method

Polishing Device

A “MA-300D” manufactured By Musashino Denshi Co. was used as a polishing apparatus, and each of wafer films shown below was polished under the following conditions while supplying a slurry.

| Number of rotation of table: | 112 | rpm |
|---|---|---|
| Number of rotation of head: | 113 | rpm |
| Polishing pressure: | 18.4 | kPa |
| Polishing pad: | IC1400 XY-K-Pad, manufactured | |
| | by Nitta Haas Inc. | |
| Polishing liquid supply rate: | 50 | ml/min |

Measurement of ζ Potential of Polishing Particle

The ζ potential at the surface of the colloidal silica particle A1 included in the polishing liquid of Example 1 was measured by DT-1200, manufactured by Nihon Rufuto Co. Ltd. The ζ potential with no addition of tetrabutylammonium nitrate was −4 mV, and the ζ potential after addition thereof was +20 mV.

An object of polishing used for the evaluation of the polishing rate and the evaluation of specifying the slit by using the polishing liquid of Example 1 was as shown below.

### Evaluation of Polishing Rate: Object of Polishing

As an object of polishing, a cut wafer prepared by cutting an 8 inch wafer in which a copper film had been formed on an Si substrate to 6 cm×6 cm was used. The cut wafer was dipped in an oxidizing agent to modify the surface with copper oxide, and the resultant wafer was used for polishing to evaluate the polishing rates for copper oxide before and after the addition of the cationic compound.

Slit Property: Object of Polishing

An object of polishing was prepared as follows. A wafer was subjected to pattering by a photolithographic process and a reactive ion etching process to attain a low dielectric constant (k=2.2). Then, a wiring of a copper-manganese alloy film was formed thereon, and the resultant wafer was subjected to heat treatment so that an Mn barrier film having a thickness of 3 nm was formed by self-organization. Then, the thus-prepared patterned wafer was cut into 6 cm×6 cm, and the cut wafer was used as the object of polishing (the stacked structure of the wafer used was as follows: insulating layer having thickness of 150 nm/Mn barrier layer having a thickness of 3 nm/Cu wiring layer).

Evaluation for Polishing Rate

The polishing rate was determined by measuring the thicknesses of the Cu film (copper oxide film) before and after the CMP, respectively, and converting them according to the following equation.

Polishing rate (nm/min)=(Thickness of each film before polishing−thickness of each film after polishing)/polishing time

The results are shown in Table 2.

Evaluation for Slit

The object of polishing was polished with the same Cu-CMP slurry for a period of time corresponding to OP+10%, and the resultant wafer was used for the evaluation of the slit. The wafer was polished with each of the polishing particles shown in Table 1 (colloidal silica particles) for 45 seconds, and the end of the 45 -second polishing was defined as completion of polishing. After the completion of the polishing, it was confirmed by visual observation whether the insulating layer was exposed over the entire wafer surface. After the treatment, the step height at the boundary between the copper wiring and the insulating layer of the wafer was measured for slit evaluation in a 0.1 μm/0.1 μm line/space area by using a probe step height measuring apparatus: Dektak V32OSi (manufactured by Veeco Instruments, Inc.). The slit after Cu-CMP was 10 nm. The results are shown in Table 2.

### Examples 2 to 20, and Comparative Examples 1 to 3

Polishing liquids having compositions and pH shown in the following Table 2 or Table 3 were prepared in the same manner as in Example 1 except that the colloidal silica particles (polishing particles), the corrosion inhibiting agent, and the cationic compound used in Example 1 were changed to components shown in Table 2 or 3, and that a complexing agent or other components was optionally added. The thus-obtained polishing liquids of Examples 2 to 20 and Comparative Examples 1 to 3 were evaluated in the same manner as in Example 1. The results are shown in Table 2 and Table 3. The polishing particles A1 to A5 are as shown in Table 1.

TABLE 2

| | | Polishing | | Corrosion inhibiting | | Cationic | | Complexing | |
|---|---|---|---|---|---|---|---|---|---|
| | | particles | | agent | | compound | | agent | |
| | | | Amount | | Amount | | Amount | | Amount |
| | | Kind | (g/L) | Kind | (g/L) | Kind | (g/L) | Kind | (g/L) |
| Example | 1 | A1 | 100 | BTA | 1 | TBA | 1 | | |
| | 2 | A2 | 200 | 5-Ph | 1 | C1 | 0.5 | | |
| | | | | tetrazole | | | | | |
| | 3 | A1 | 150 | BTA | 3 | TBA | 5 | Citric | 2 |
| | | A3 | 150 | | | | | Acid | |
| | 4 | A4 | 200 | MBTA | 2 | TMA | 3 | | |
| | 5 | A5 | 50 | 1H-tetrazole | 0.5 | C2 | 2 | | |
| | 6 | A1 | 300 | BTA | 1 | TPA | 1 | | |
| | 7 | A3 | 400 | BTA | 3 | C2 | 0.1 | | |
| | 8 | A1 | 100 | 5-Me | 2 | TMA | 1 | Citric | 2 |
| | | | | tetrazole | | | | Acid | |
| | 9 | A2 | 150 | MBTA | 2 | TBA | 5 | | |
| | 10 | A4 | 200 | 1H-tetrazole | 0.5 | TBA | 3 | Citric | 2 |
| | | | | | | | | acid | |
| | 11 | A1 | 300 | BTA | 1 | C1 | 2 | | |

| | | | | | ζ potential of | | | | |
|---|---|---|---|---|---|---|---|---|---|
| | | | | | polishing | | Cu polishing | | |
| | | | | | particles | | rate | | |
| | | | | | (mV) | | (nm/min) | | |
| | | | | | Cationic | | Cationic | | |
| | | Other components | | | compound | | compound | | |
| | | | Amount | | Not | | Not | | Slit |
| | | Kind | (g/L) | pH | added | Added | added | Added | (nm) |
| Example | 1 | | | 2.5 | −4 | 20 | 60 | 20 | 10 |
| | 2 | Polyacrylic acid | 0.2 | 3.5 | −5 | 15 | 51 | 10 | 8 |
| | 3 | Betaine: | 0.05 | 2.5 | −3 | 18 | 37 | 18 | 16 |
| | | N,N,N- | | | | | | | |
| | | trimethyl- | | | | | | | |
| | | ammonio | | | | | | | |
| | | Acetate | | | | | | | |
| | 4 | | | 3.5 | −6 | 20 | 43 | 12 | 13 |
| | 5 | | | 2 | −2 | 16 | 65 | 15 | 15 |
| | 6 | Polyvinyl | 0.5 | 5 | −10 | 7 | 45 | 10 | 20 |
| | | alcohol | | | | | | | |
| | 7 | | | 2.5 | −5 | 10 | 63 | 7 | 10 |
| | 8 | | | 3.5 | −6 | 20 | 31 | 17 | 7 |
| | 9 | Betaine: | 0.05 | 3.5 | −4 | 25 | 67 | 17 | 11 |
| | | N,N,N- | | | | | | | |
| | | trimethyl | | | | | | | |
| | | ammonio | | | | | | | |
| | | Acetate | | | | | | | |
| | 10 | | | 2.5 | −3 | 13 | 31 | 10 | 20 |
| | 11 | Polymethacrylic | 0.2 | 2 | −1 | 9 | 45 | 20 | 10 |
| | | acid | | | | | | | |

TABLE 3

| | | Polishing | | Corrosion inhibiting | | Cationic | | Complexing | |
|---|---|---|---|---|---|---|---|---|---|
| | | particles | | agent | | compound | | agent | |
| | | | Amount | | Amount | | Amount | | Amount |
| | | Kind | (g/L) | Kind | (g/L) | Kind | (g/L) | Kind | (g/L) |
| Example | 12 | A2 | 150 | 5-Ph | 1 | TPA | 1 | | |
| | | A3 | 150 | tetrazole | | | | | |
| | 13 | A1 | 100 | MBTA | 2 | TBA | 0.5 | | |
| | 14 | A3 | 300 | BTA | 1 | C3 | 1 | | |
| | 15 | A1 | 100 | BTA | 1 | TBA | 0.1 | | |
| | 16 | A3 | 200 | 1H-tetrazole | 0.5 | TBA | 1 | | |
| | | A4 | 200 | | | | | | |
| | 17 | A2 | 100 | BTA | 1 | TBA | 1 | | |
| | 18 | A5 | 200 | MBTA | 2 | C1 | 1 | | |
| | 19 | A1 | 100 | MBTA | 2 | TPA | 1 | | |
| | 20 | A3 | 250 | BTA | 1 | C2 | 0.5 | Citric | 2 |
| | | | | | | | | Acid | |
| Comp. Example | 1 | A1 | 100 | BTA | 1 | | | | |
| | 2 | A1 | 100 | | | TBA | 1 | | |
| | 3 | | | BTA | 1 | TBA | 1 | | |

| | | | | | ζ potential of | | | | |
|---|---|---|---|---|---|---|---|---|---|
| | | | | | polishing | | Cu polishing | | |
| | | | | | particles | | rate | | |
| | | | | | (mV) | | (nm/min) | | |
| | | | | | Cationic | | Cationic | | |
| | | Other components | | | compound | | compound | | |
| | | | Amount | | Not | | Not | | Slit |
| | | Kind | (g/L) | pH | added | Added | added | Added | (nm) |
| Example | 12 | | | 2 | −2 | 26 | 68 | 15 | 15 |
| | 13 | Betaine: | 0.05 | 4 | −12 | 5 | 54 | 17 | 25 |
| | | N,N,N- | | | | | | | |
| | | trimethyl- | | | | | | | |
| | | ammonio | | | | | | | |
| | | Acetate | | | | | | | |
| | 14 | | | 3.5 | −5 | 16 | 30 | 19 | 15 |
| | 15 | | | 3.5 | −3 | 13 | 45 | 20 | 16 |
| | 16 | | | 3.5 | −4 | 21 | 23 | 25 | 19 |
| | 17 | | | 5 | −10 | 14 | 54 | 30 | 24 |
| | 18 | | | 3 | −2 | 17 | 42 | 12 | 23 |
| | 19 | Polyacrylic | 0.2 | 2 | −1 | 22 | 61 | 20 | 13 |
| | | acid | | | | | | | |
| | 20 | | | 4 | −7 | 10 | 37 | 18 | 10 |
| Comp. Example | 1 | | | 3.5 | −4 | — | 60 | — | 30 |
| | 2 | | | 3.5 | −4 | 20 | 300 | 250 | >100 |
| | 3 | | | 3.5 | — | — | 1 | 0 | Evaluation |
| | | | | | | | | | impossible |

In Table 2 and Table 3, “BTA” and “MBTA” in the column for the corrosion inhibiting agent indicate benzotriazole and methyl benzotriazole, respectively. Further, in the column for the corrosion agent, “5 -Ph tetrazole” and “5 -Me tetrazole” indicate 5 -phenyl tetrazole and 5 -methyl tetrazole, respectively.

In Table 2 and Table 3, “TMA”, “TPA”, and “TBA” in the column for the cationic compound indicate tetramethylammonium nitrate, tetrapropylammonium, and tetrabutylammonium, respectively, which are the cationic compounds represented by Formula (I). Further, “C1” to “C3” are Exemplary Compounds C1 to C3 of the cationic compounds represented by Formula (II).

In Table 3, “−” in the column for the ζ potential of the polishing particle in Comparative Example 1 shows that the ζ potential at the surface of the colloidal silica particle was not able to be measured. Regarding Comparative Example 3, since polishing particles were not used, the ζ potential at the surface of the colloidal silica particle was not measured.

Further, in Table 3, “−” in the column for Cu polishing rate shows that Cu polishing rate was not able to be measured.

As shown in Table 2 and Table 3, it has been found that the value for the slit evaluation is small and the step height between the copper wiring and the insulating layer is small when the polishing liquids of the invention (Examples 1 to 20 ) are used, compared with the case in which the polishing liquids of Comparative Examples are used.

What is claimed is:

1. A polishing liquid, comprising:
colloidal silica particles exhibiting a positive ζ potential at the surface thereof, a corrosion inhibiting agent; and
an oxidizing agent,
wherein the polishing liquid is used for polishing a barrier layer mainly comprising manganese and/or a manganese alloy and an insulating layer in a chemical mechanical polishing process for a semiconductor device having, on a surface thereof, the barrier layer, a conductive metal wiring, and the insulating layer.

2. The polishing liquid according to claim 1, wherein the colloidal silica exhibiting a positive ζ potential at the surface thereof comprises a colloidal silica in which a cationic compound represented by the following Formula (I) or the following Formula (II) is adsorbed onto the surface of a colloidal silica having a negative charge: 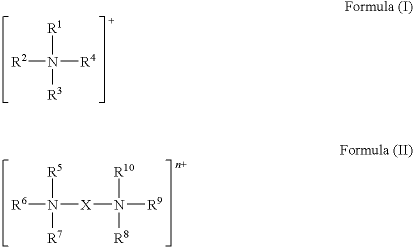
wherein, R¹ to R⁴ in Formula (I) and R⁵ to R¹⁰ in Formula (II) each independently represent an alkyl group having 1 to 20 carbon atoms, an alkenyl group, a cycloalkyl group, an aryl group, or an aralkyl group; two of R¹ to R⁴ may bond to each other; two of R⁵ to R¹⁰ may bond to each other; the substituents represented by R¹ to R⁴ and R⁵ to R¹⁰ each may be further substituted by another substituent; X in Formula (II) represents an alkylene group having 1 to 30 carbon atoms, an alkenylene group, a cycloalkylene group, an arylene group or a linking group having a combination of two or more of these groups; the linking group may further be substituted by another substituent; X may further include a nitrogen atom in a quaternary amine form in a structure thereof, and n in Formula (II) represents an integer of 2 or larger.

3. The polishing liquid according to claim 2, wherein the concentration of the cationic compound represented by Formula (I) or Formula (II) is from 0.00005 mass % to 1 mass % with respect to the entire mass of the polishing liquid when used in polishing.

4. The polishing liquid according to claim 1, wherein the barrier layer comprising the manganese and/or a manganese alloy is formed near the boundary between the conductive metal wiring and the insulating layer by self organization of a manganese compound due to excitation energy.

5. The polishing liquid according to claim 1, wherein the insulating layer comprises a low-dielectric-constant insulating layer having silicon as a basic skeleton and having a dielectric constant (k value) of 2.3 or less.

6. The polishing liquid according to claim 1, wherein the concentration of the colloidal silica exhibiting a positive ζ potential at the surface thereof is from 0.5 mass % to 10 mass % with respect to the entire mass of the polishing liquid when used in polishing.

7. The polishing liquid according to claim 1, wherein the primary average particle diameter of the colloidal silica exhibiting a positive ζ potential at the surface thereof is from 5 nm to 100 nm.

8. The polishing liquid according to claim 1, wherein the concentration of the corrosion inhibiting agent is from 0.001 mass % to 1 mass % with respect to the entire mass of the polishing liquid when used in polishing.

9. The polishing liquid according to claim 1, wherein the polishing liquid is free from a complexing agent.

10. The polishing liquid according to claim 1, wherein the polishing liquid has a pH of from 1.5 to 5.0.

11. The polishing liquid according to claim 1, further comprising a zwitterionic compound.

12. The polishing liquid according to claim 1, further comprising a carboxylic acid polymer.

13. A method of polishing a barrier layer mainly comprising manganese and/or a manganese alloy and an insulating layer in a chemical mechanical polishing process for a semiconductor device having, on a surface thereof, the barrier layer, a conductive metal wiring, and the insulating layer, the method comprising:
polishing the barrier layer and the insulating layer using a polishing liquid comprising a colloidal silica particle exhibiting a positive ζ potential at the surface thereof, a corrosion inhibiting agent, and an oxidizing agent.

14. The polishing method according to claim 13, wherein the colloidal silica exhibiting a positive ζ potential at the surface thereof comprises a colloidal silica in which a cationic compound represented by the following Formula (I) or the following Formula (II) is adsorbed onto the surface of a colloidal silica having a negative charge: 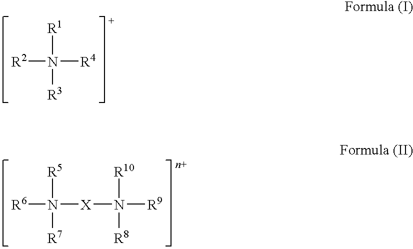
wherein R¹ to R⁴ in Formula (I) and R⁵ to R¹⁰ in Formula (II) each independently represent an alkyl group having 1 to 20 carbon atoms, an alkenyl group, a cycloalkyl group, an aryl group, or an aralkyl group; two of R¹ to R⁴ may bond to each other; two of R⁵ to R¹⁰ may bond to each other; the substituents represented by R¹ to R⁴ and R⁵ to R¹⁰ may each be further substituted by another substituent; X in Formula (II) represents an alkylene group having 1 to 30 carbon atoms, an alkenylene group, a cycloalkylene group, an arylene group or a linking group having such groups in combination; the linking group may further be substituted by another substituent; X may further comprise a nitrogen atom in a quaternary amine form in a structure thereof, and n in Formula (II) represents an integer of 2 or larger.

15. The polishing method according to claim 14, wherein the concentration of the cationic compound represented by Formula (I) or Formula (II) is from 0.00005 mass % to 1 mass % with respect to the entire mass of the polishing liquid when used in polishing.

16. The polishing method according to claim 13, wherein the barrier layer comprising manganese and/or a manganese alloy is formed near the boundary between the conductive metal wiring and the insulating layer by self organization of the manganese compound due to excitation energy.

17. The polishing method according to claim 13, wherein the insulating layer comprises a low-dielectric-constant insulating layer having silicon as a basic skeleton and having a dielectric constant (k value) of 2.3 or less.
